(19) United States
(12) Patent Application Publication
(10) Pub. No.: US 2025/0297869 A1
(43) Pub. Date: Sep. 25, 2025

(54) SENSOR DEVICE

(71) Applicant: ALPS ALPINE CO., LTD., Tokyo (JP)

(72) Inventors: Takashi SASAKI, Miyagi (JP); Ken KAMAGATA, Miyagi (JP); Keito OSAKI, Miyagi (JP)

(21) Appl. No.: 19/081,298

(22) Filed: Mar. 17, 2025

(30) Foreign Application Priority Data
Mar. 25, 2024 (JP) 2024-047922

(51) Int. Cl. G01D 5/24; B62D 1/06; H05B 1/02

(52) U.S. Cl. CPC G01D 5/24; H05B 1/0236; B62D 1/06

(57) ABSTRACT

To provide a sensor device having good detection sensitivity and simple configuration, a sensor device includes: a sensor electrode operable as a heating element; an electrostatic detection circuit for detecting capacitance of the sensor electrode; a high-side MOSFET provided between a power source for supplying power for heating and the sensor electrode; a low-side MOSFET provided between the sensor electrode and a reference potential point; a node positioned between high-side MOSFET or low-side MOSFET and the sensor electrode; and a controller for controlling high-side MOSFET and low-side MOSFET, wherein the controller controls high-side MOSFET and low-side MOSFET to be in electrical conduction with each other when supplying power for heating from the power source to the sensor electrode, and controls high-side MOSFET and low-side MOSFET to be in an open state and applies a predetermined voltage to the node when detecting the capacitance with the electrostatic detection circuit.

### CROSS-REFERENCE TO RELATED APPLICATION

The present application claims priority under 35 U.S.C. § 119 to Japanese Patent Application No. 2024-047922, filed Mar. 25, 2024, the contents of which are incorporated herein by reference in their entireties.

### BACKGROUND OF THE INVENTION

### Field of the Invention

This disclosure relates to a sensor device.

### Description of the Related Art

Conventionally, there has been a sensor device that includes: an electrode body including a heating element serving as a sensor electrode; a detection device for detecting the capacitance of the sensor electrode; a high-side switch provided between a heating power source and the heating element; a low-side switch provided between the heating element and a reference potential point; a gate controller for opening the high-side switch and the low-side switch in a detection mode; and a decoupling circuit including a decoupling MOSFET connected between the high-side switch and the heating element. The gate controller brings the decoupling MOSFET into electrical conduction in a heating mode, and opens the decoupling MOSFET in the detection mode. In the detection mode, the decoupling circuit supplies a third potential to a first node connected between the high-side switch and the decoupling MOSFET. A potential different from the third potential is supplied to a node between the low-side switch and the heating element (see, for example, United States Patent Application Publication No. 2023/0046256).

### SUMMARY OF THE INVENTION

The existing sensor device has the complex configuration including the high-side switch, the low-side switch, the decoupling MOSFET, the first node, and the node to which the potential different from the third potential is supplied. On the other hand, the sensor device is required to have good detection sensitivity when detecting the capacitance of the sensor electrode. However, the detection sensitivity decreases due to the presence of parasitic capacitances of the MOSFETs serving as the high-side switch and the low-side switch. Therefore, it is preferable to minimize a decrease in the detection sensitivity.

It is an object to provide a sensor device having good detection sensitivity and a simple configuration.

A sensor device according to an embodiment of the present disclosure includes: a sensor electrode operable as a heating element; an electrostatic detection circuit configured to detect a capacitance between the sensor electrode and an object; a high-side switch provided between a power source for supplying power for heating to the sensor electrode and the sensor electrode; a low-side switch provided between the sensor electrode and a reference potential point; a node positioned between the high-side switch or the low-side switch and the sensor electrode; and a controller configured to control the high-side switch and the low-side switch, wherein the controller controls the high-side switch and the low-side switch to be in electrical conduction with each other when supplying the power for heating from the power source to the sensor electrode, and the controller controls the high-side switch and the low-side switch to be in an open state and applies a predetermined voltage to the node when detecting the capacitance with the electrostatic detection circuit.

A sensor device having good detection sensitivity and a simple configuration can be provided.

### BRIEF DESCRIPTION OF THE DRAWINGS

FIG. 1 is a view schematically showing a steering wheel mounted with a sensor device of an embodiment;

FIG. 2 is a diagram showing an example of the circuit configuration of a sensor device of the embodiment;

FIG. 3 is a diagram showing an example of a parasitic capacitance Coss between the drain and source of a high-side MOSFET and a low-side MOSFET of a sensor device of the embodiment;

FIG. 4A is a diagram showing an example of electrical characteristics of a high-side MOSFET;

FIG. 4B is a diagram showing an example of electrical characteristics of a low-side MOSFET;

FIG. 5A is a diagram showing an example of the circuit configuration of a part of a sensor device of a modified example of the embodiment; and

FIG. 5B is a diagram showing an example of the circuit configuration of a part of a sensor device of a modified example of the embodiment.

### DETAILED DESCRIPTION OF THE DISCLOSURE

An embodiment to which a sensor device of the present disclosure is applied will be described below.

### Embodiment

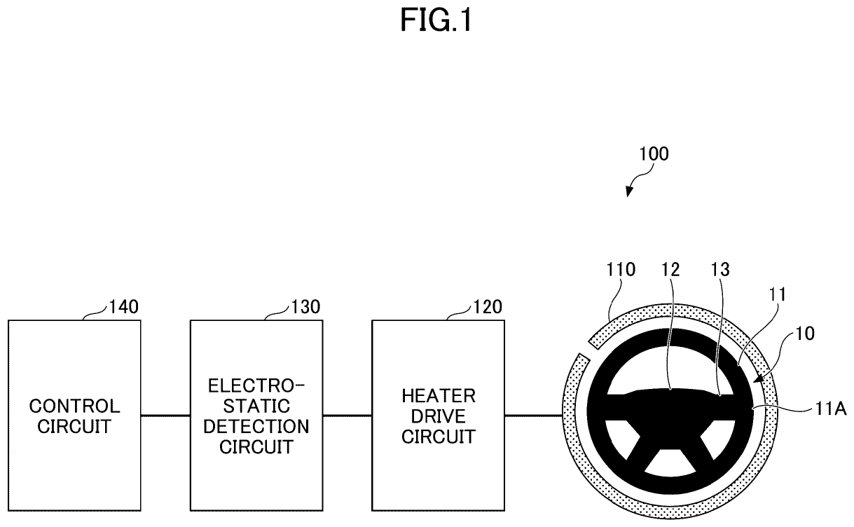

FIG. 1 is a view schematically showing a steering wheel 10 mounted with a sensor device 100 of the embodiment. The sensor device 100 includes a sensor electrode 110, a heater drive circuit 120, an electrostatic detection circuit 130, and a control circuit 140. The control circuit 140 is an example of a controller.

The steering wheel 10 is mounted on a vehicle, and the sensor electrode 110 of the sensor device 100 is mounted on the inner side of a skin 11A of a rim 11. The sensor electrode 110 is an example of a sensor electrode operable as a heating element. The sensor device 100 determines whether a driver's hand is in contact with the rim 11 of the steering wheel 10. The sensor device 100 warms the steering wheel 10 by supplying power for heating to the sensor electrode 110. That is, the sensor device 100 has both the functions as a Hands On Detection (HOD) and as a steering wheel heater. A hand is an example of an object. The rim 11 of the steering wheel 10 is an example of a fixing part to which the sensor electrode 110 is fixed. The skin 11A of the rim 11 is an example of a contact part which the detection object can contact.

Hereinafter, the driver of a vehicle is referred to as the operator of the sensor device 100. The operator's touching the rim 11 of the steering wheel 10 provided with the sensor electrode 110 is referred to as an operator's operation.

The steering wheel 10 has the rim 11, a hub 12, and a spoke 13. Those that are shown as the rim 11, the hub 12, and the spoke 13 in FIG. 1 are the core metal parts of the rim 11, the hub 12, and the spoke 13. In FIG. 1, in order to show the sensor electrode 110, the sensor electrode 110 is shown apart from the skin 11A of the rim 11. In FIG. 1, a cover covering the hub 12 and the spoke 13 is omitted.

A ground terminal of the steering wheel 10 is electrically connected to the core metal provided along the whole circumference of the rim 11 of the steering wheel 10. With the core metal connected to a ground terminal of the heater drive circuit 120, the electrostatic detection circuit 130, and the control circuit 140 via a connector (not shown), the ground potential of the heater drive circuit 120, the electrostatic detection circuit 130, and the control circuit 140 is equal to the ground potential of the steering wheel 10.

### Schematic Configuration of Sensor Device 100

The sensor device 100 includes the sensor electrode 110, the heater drive circuit 120, the electrostatic detection circuit 130, and the control circuit 140. The control circuit 140 may be an Electronic Control Unit (ECU). FIG. 1 shows a simplified connection relationship between the sensor electrode 110, the heater drive circuit 120, the electrostatic detection circuit 130, and the control circuit 140. The control circuit 140 is also connected to the heater drive circuit 120 via a cable, a connector, or the like not shown.

The sensor device 100 has two modes: a heating mode of supplying power for heating to the sensor electrode 110 from the power source of a vehicle, and a non-heating mode of stopping supply of the power for heating to the sensor electrode 110. The sensor device 100 may detect the capacitance using the electrostatic detection circuit 130 in the non-heating mode. The control circuit 140 switches between the two modes in a time-division manner. In other words, the control circuit 140 alternatively switches between the heating mode and the non-heating mode in accordance with the passage of time.

### Sensor Electrode 110

The sensor electrode 110 is provided along the whole circumference of the rim 11 of the steering wheel 10 in a state insulated from the core metal provided along the whole circumference of the rim 11 of the steering wheel 10. The sensor electrode 110 is connected to the heater drive circuit 120, the electrostatic detection circuit 130, and the control circuit 140 via a signal line or the like. The sensor electrode 110 is a thin sheet-like belt-like electrode provided along the whole circumference of the rim 11, and can be produced by, for example, applying a conductive material such as a silver paste or the like to the surface of a resin film.

### Heater Drive Circuit 120

The heater drive circuit 120 is connected to the sensor electrode 110 and supplies power for heating to the sensor electrode 110 from the power source of a vehicle in the heating mode.

### Electrostatic Detection Circuit 130

The electrostatic detection circuit 130 is connected to the sensor electrode 110 and detects the capacitance between the sensor electrode 110 and the operator's hand.

### Control Circuit 140

The control circuit 140 is implemented by a computer including a Central Processing Unit (CPU), a Random Access Memory (RAM), a Read Only Memory (ROM), an input/output interface, an internal bus, and the like. The control circuit 140 switches the mode of the sensor device 100 between the heating mode and the non-heating mode. The control circuit 140 controls a high-side MOSFET 121 and a low-side MOSFET 122. The control circuit 140 brings both the high-side MOSFET 121 and the low-side MOSFET 122 into a conductive state (ON) in the heating mode. The control circuit 140 brings the high-side MOSFET 121 and the low-side MOSFET 122 into a non-conductive state (OFF) in the non-heating mode.

### Circuit Configuration of Sensor Device 100

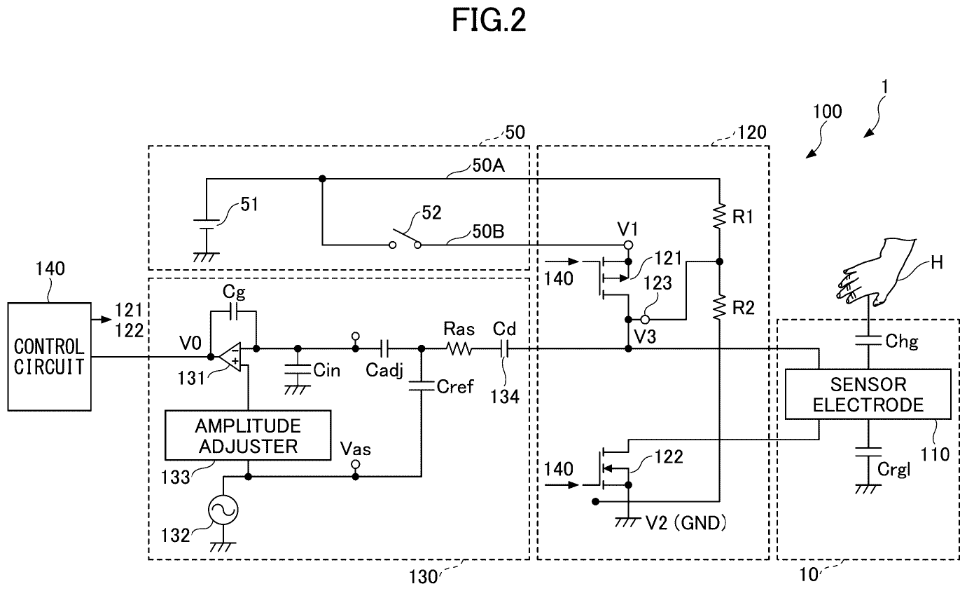

FIG. 2 shows an example of the circuit configuration of the sensor device 100. FIG. 2 also shows a power source circuit 50 of a vehicle 1 on which the sensor device 100 is mounted. The power source circuit 50 includes a power source 51 and a relay 52. As an example, the power source 51 is a battery of the vehicle 1. Although descriptions will be based on that the power source 51 of FIG. 2 is a battery, the power source 51 may include a power generator, a regeneration device, or the like of the vehicle 1 in addition to the battery. The output voltage of the power source 51 is V1.

The power source circuit 50 has two power source paths 50A and 50B. The power source paths 50A and 50B are both connected to the power source 51 and branched in the middle. The relay 52 is inserted in series on the power source path 50B.

### Sensor Electrode 110

The sensor electrode 110 is provided on the steering wheel 10 and connected to the heater drive circuit 120. More specifically, as shown in FIG. 1, the sensor electrode 110 is a conductor having ends on both sides. One end is connected to the drain of the high-side MOSFET 121 and a node 123. The other end of the sensor electrode 110 is connected to the drain of the low-side MOSFET 122.

A parasitic capacitance between the sensor electrode 110 and a ground potential point is Crgl, and a capacitance between the sensor electrode 110 and a hand H is Chg. The capacitance Chg varies greatly depending on whether the hand H is in contact with the sensor electrode 110.

### Heater Drive Circuit 120

The heater drive circuit 120 includes the high-side MOSFET 121, the low-side MOSFET 122, the node 123, a resistor R1, and a resistor R2. The high-side MOSFET 121 is an example of a high-side switch, and the low-side MOSFET 122 is an example of a low-side switch. The resistor R1 is an example of a first voltage-dividing resistor, and the resistor R2 is an example of a second voltage-dividing resistor.

The high-side MOSFET 121 is, for example, a P-channel MOSFET, in which the source is connected to the power source 51 via the relay 52 via a node V1, the drain is connected to the sensor electrode 110 and the node 123, and the gate is connected to the control circuit 140. The node V1 is a node at which the voltage value is V1, and is located between the source of the high-side MOSFET 121 and the relay 52. The high-side MOSFET 121 is provided between the power source 51 and the sensor electrode 110, and is driven by a PWM-type gate drive signal supplied from the control circuit 140 to the gate.

The low-side MOSFET 122 is, for example, an N-channel MOSFET, in which the drain is connected to the sensor electrode 110 and the node 123, the source is connected to a node V2, and the gate is connected to the control circuit 140. The node V2 is a node at which the voltage value is V2 (<V3<V1), and is an example of a reference potential point maintained at the ground potential. The low-side MOSFET 122 is provided between the sensor electrode 110 and the node V2, and is driven by a gate drive signal supplied from the control circuit 140 to the gate.

The node 123 is connected between the resistors R1 and R2, and furthermore, a voltage V3 obtained by dividing a DC power (voltage V1) supplied from the power source 51 to the resistor R1 in accordance with the resistors R1 and R2 is supplied to the node 123. The voltage V3 is an example of a predetermined voltage. The node 123 is connected between the resistors R1 and R2, and between the drain of the high-side MOSFET 121, the sensor electrode 110, and a capacitor 134 of the electrostatic detection circuit 130.

### Electrostatic Detection Circuit 130

The electrostatic detection circuit 130 includes a charge amplifier 131, an Alternating-Current (AC) signal source 132, an amplitude adjuster 133, and a capacitor Cd. The electrostatic detection circuit 130 detects the capacitance of the sensor electrode 110 in the non-heating mode. The AC signal source 132 is an example of a sinusoidal signal source.

The charge amplifier 131 includes a non-inverting input terminal (+) connected to the output terminal of the amplitude adjuster 133, an inverting input terminal (−) connected to the sensor electrode 110 via the capacitor Cd, and an output terminal connected to the control circuit 140. The output voltage of the output terminal of the charge amplifier 131 is V0. The charge amplifier 131 is a differential amplifier that amplifies the difference between the input into the non-inverting input terminal (+) and the input into the inverting input terminal (−) and outputs an output signal.

The AC signal source 132 is connected to the amplitude adjuster 133 and to the sensor electrode 110 via the capacitor Cd. The AC signal source 132 outputs an AC signal (sinusoidal signal) for driving the sensor electrode 110. The AC signal source 132 may output an AC signal for driving the sensor electrode 110 only in the non-heating mode.

The amplitude adjuster 133 performs amplitude adjustment such that the difference between the inverting input terminal (−) and the non-inverting input terminal (+) is eliminated and the output V0 is minimized when no hand H, which is the object, is present close to the sensor electrode 110 (when the parasitic capacitance Crg is 0).

The capacitor Cd has a terminal (left terminal in FIG. 2) that is connected to the inverting input terminal (−) of the charge amplifier 131 and to the amplitude adjuster 133, and a terminal that is connected to the sensor electrode 110. Namely, the capacitor Cd is inserted in series between the inverting input terminal (−) of the charge amplifier 131 and the sensor electrode 110. The capacitor Cd is an example of a capacitor for Direct-Current (DC) separation provided between the heater drive circuit 120 and the electrostatic detection circuit 130 in order to cut off a DC component.

### Control Circuit 140

In the non-heating mode, the control circuit 140 outputs a gate drive signal having an H (High) level to the gate of the high-side MOSFET 121 and outputs a gate drive signal having an L (Low) level to the gate of the low-side MOSFET 122. As a result, the high-side MOSFET 121 and the low-side MOSFET 122 enter a non-conductive state (OFF). When the high-side MOSFET 121 and the low-side MOSFET 122 are in the non-conductive state (OFF), the sensor electrode 110 is not affected by the power source circuit 50.

In the non-heating mode, the control circuit 140 converts the signal output from the charge amplifier 131 into a digital signal, and demodulates it using a demodulation signal having the same frequency as that of the AC signal. Based on the demodulation output, the control circuit 140 determines whether or not the hand H is touching the sensor electrode 110.

In the heating mode, the control circuit 140 outputs the gate drive signal having the L level to the gate of the high-side MOSFET 121 and outputs the gate drive signal having the H level to the gate of the low-side MOSFET 122. As a result, the high-side MOSFET 121 and the low-side MOSFET 122 enter a conductive state (ON).

When the temperature of the steering wheel 10 is under the target temperature, the control circuit 140 periodically switches the gate drive signals output to the gates of the high-side MOSFET 121 and the low-side MOSFET 122. Any time other than the time required for detecting the capacitance of the sensor electrode 110, the high-side MOSFET 121 and the low-side MOSFET 122 are in the conductive state (ON) to heat the sensor electrode 110. On the other hand, when the temperature of the steering wheel 10 is above the target temperature, the control circuit 140 keeps the high-side MOSFET 121 and the low-side MOSFET 122 in an open state (OFF). In a case of switching the power for heating between multiple stages, the control circuit 140 may perform PWM control of the high-side MOSFET 121 and the low-side MOSFET 122. In this case, the control circuit 140 may determine the duty ratio of the PWM signal by feedback control based on the target temperature of the heater of the steering wheel 10, the current temperature of the heater of the steering wheel 10, and the like. The temperature of the heater of the steering wheel 10 may be measured by a temperature sensor that may be provided on the steering wheel 10.

### Parasitic Capacitance of High-Side MOSFET 121 and Low-Side MOSFET 122

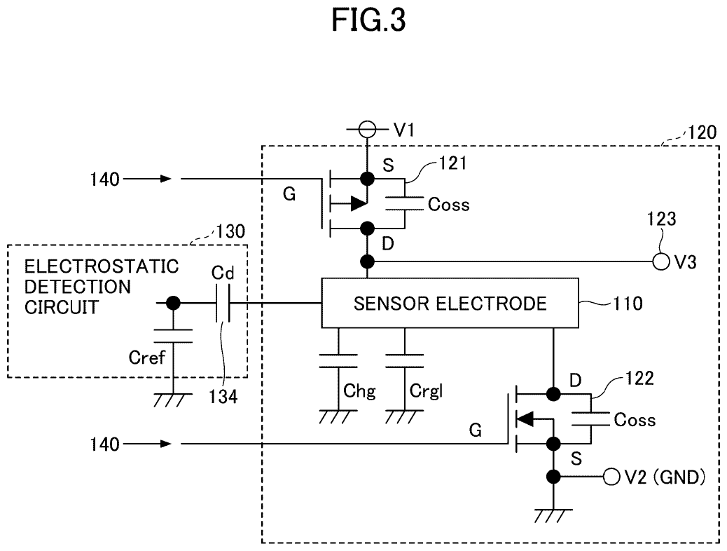

FIG. 3 shows an example of parasitic capacitances Coss between the drain and the source of the high-side MOSFET 121 and those of the low-side MOSFET 122. The parasitic capacitance Coss of the high-side MOSFET 121 is an example of a first parasitic capacitance, and the parasitic capacitance Coss of the low-side MOSFET 122 is an example of a second parasitic capacitance.

FIG. 3 shows the sensor electrode 110, the high-side MOSFET 121, the low-side MOSFET 122, the node 123, the capacitor 134 of the electrostatic detection circuit 130, and the like among the components shown in FIG. 2, and the other components are omitted.

The parasitic capacitances Coss exist between the drain and the source of the high-side MOSFET 121 and the low-side MOSFET 122. A MOSFET has an electrical characteristic in which the parasitic capacitance Coss between the drain and the source changes with respect to the voltage across the drain and the source. In general, the higher the voltage across the drain and the source, the less the parasitic capacitance Coss.

Therefore, in the P-channel high-side MOSFET 121, the higher the voltage of the source with respect to the drain, the less the parasitic capacitance Coss. In the N-channel low-side MOSFET 122, the higher the voltage of the drain with respect to the source, the less the parasitic capacitance Coss.

The parasitic capacitances Coss affect the detection sensitivity in detecting the capacitance of the sensor electrode 110. That is, in order to obtain good detection sensitivity by minimizing a decrease in the detection sensitivity in the non-heating mode for detecting the capacitance of the sensor electrode 110, it is preferable that the parasitic capacitances Coss of the high-side MOSFET 121 and the low-side MOSFET 122 are small values of a certain level in the sensor device 100.

In the sensor device 100, in order to reduce the parasitic capacitances Coss of the high-side MOSFET 121 and the low-side MOSFET 122, the node 123 is connected between the drain of the P-channel high-side MOSFET 121 and the sensor electrode 110.

The voltage V3 supplied to the node 123 is lower than the voltage V1 supplied to the source of the high-side MOSFET 121 and higher than the voltage V2 (GND) supplied to the source of the low-side MOSFET 122.

Therefore, by appropriately setting the voltage V3, it is possible to realize the source-drain voltage that can reduce the parasitic capacitance Coss of the high-side MOSFET 121 and the drain-source voltage that can reduce the parasitic capacitance Coss of the low-side MOSFET 122.

It is possible to adjust the voltage V3 by adjusting the ratio between the resistance values of the resistors R1 and R2. On this premise, it is assumed that the high-side MOSFET 121 and the low-side MOSFET 122 are equal to each other in the electrical characteristics in which the parasitic capacitance Coss changes with respect to the voltage across the drain and the source. This is because it is easy to set the parasitic capacitances Coss of the high-side MOSFET 121 and the low-side MOSFET 122 when the electrical characteristics of the high-side MOSFET 121 and the electrical characteristics of the low-side MOSFET 122 are equal to each other.

In this case, the voltage V3 needs only to be an intermediate voltage between the voltage V1 and the voltage V2 (GND), and the voltage V3 is preferably a voltage obtained by adding 40% to 60% the voltage difference between the voltages V1 and V2 to the voltage V2, and most preferably a voltage obtained by adding 50% the voltage difference between the voltages V1 and V2. That is, the voltage V3 is most preferably a voltage obtained by adding half the voltage difference between the voltages V1 and V2 to the voltage V2.

In other words, the voltage V3 may be a voltage that makes the parasitic capacitance Coss of the high-side MOSFET 121 and the parasitic capacitance Coss of the low-side MOSFET 122 equal to or similar to each other. The parasitic capacitance Coss of the high-side MOSFET 121 and the parasitic capacitance Coss of the low-side MOSFET 122 being equal to or similar to each other means, for example, that the difference between the parasitic capacitance Coss of the high-side MOSFET 121 and the parasitic capacitance Coss of the low-side MOSFET 122 is within ±10%.

### Example of Electrical Characteristics of High-Side MOSFET 121 and Low-Side MOSFET 122 in Sensor Device 100

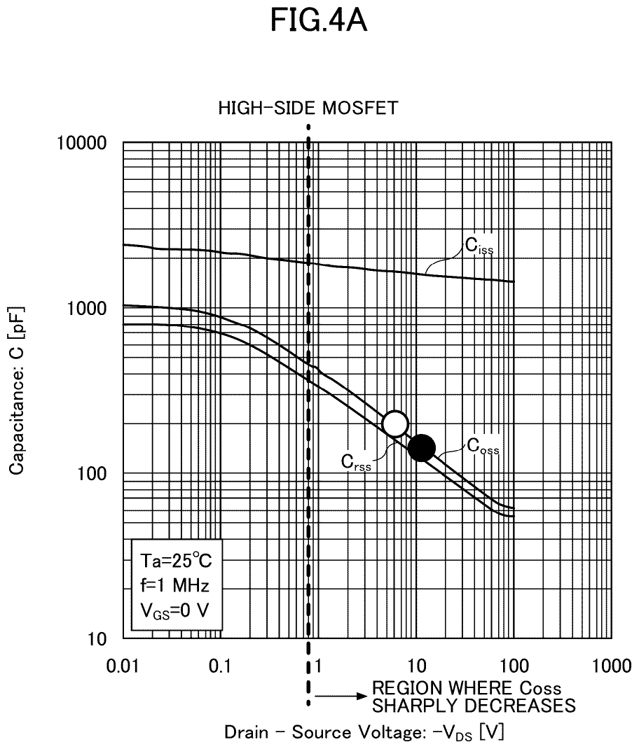

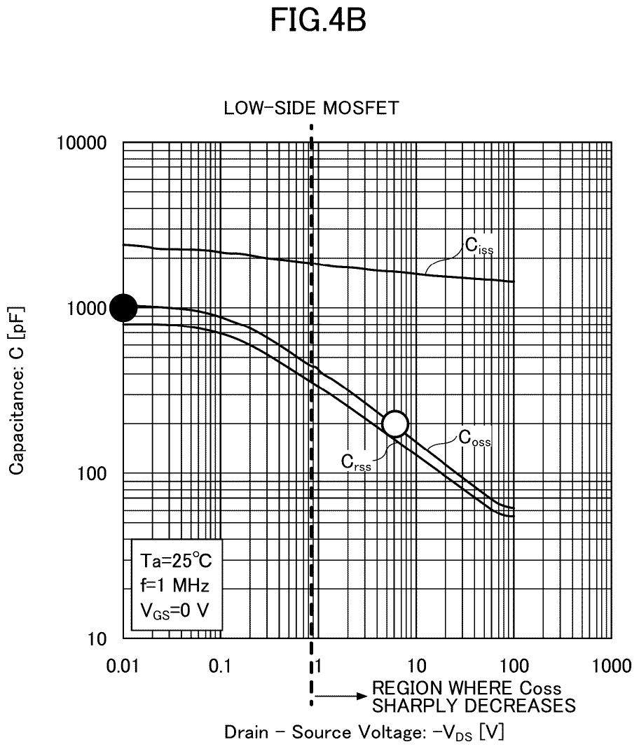

FIG. 4A shows an example of the electrical characteristics of the high-side MOSFET 121. FIG. 4B shows an example of the electrical characteristics of the low-side MOSFET 122. In FIG. 4A, the horizontal axis represents the voltage VSD (V) of the source to the drain of the P-channel high-side MOSFET 121. In FIG. 4B, the horizontal axis represents the voltage VDS (V) of the drain to the source of the N-channel low-side MOSFET 122. In FIGS. 4A and 4B, the vertical axis represents the parasitic capacitance Coss (pF). In FIGS. 4A and 4B, a region on the horizontal axis where the voltage is equal to or higher than approximately 1 V is a region where the parasitic capacitance Coss sharply decreases.

In describing the electrical characteristics of the high-side MOSFET 121 and the low-side MOSFET 122 of the sensor device 100, the electrical characteristics of a high-side MOSFET 121 and a low-side MOSFET 122 of a comparative sensor device will also be described.

The comparative sensor device has the configuration of the sensor device 100 of the embodiment from which the node 123 is omitted. In the comparative sensor device without the node 123, the drain voltage of the high-side MOSFET 121 is lower and the drain voltage of the low-side MOSFET 122 is lower than those of the sensor device 100 of the embodiment.

That is, in the comparative sensor device, the source-drain voltage VSD of the high-side MOSFET 121 is higher and the drain-source voltage VDS of the low-side MOSFET 122 is lower than those of the sensor device 100 of the embodiment.

Therefore, in the comparative sensor device, the parasitic capacitance Coss of the high-side MOSFET 121 is less and the parasitic capacitance Coss of the low-side MOSFET 122 is greater than those of the sensor device 100 of the embodiment.

That is, the parasitic capacitance Coss of the high-side MOSFET 121 of the comparative sensor device is, for example, a small value (approximately 150 pF) as indicated by a black circle (●) in FIG. 4A, and the parasitic capacitance Coss of the low-side MOSFET 122 of the comparative sensor device is, for example, a large value (approximately 1,000 pF) as indicated by a black circle (●) in FIG. 4B. The sum of the two parasitic capacitances Coss is approximately 1,150 pF, and this total parasitic capacitance is the parasitic capacitance Crgl between the sensor electrode 110 and the ground potential point. This means that the parasitic capacitance Crgl between the sensor electrode 110 and the ground potential point is extremely large.

In the comparative sensor device, the parasitic capacitance Coss of the low-side MOSFET 122 is large due to the source-drain voltage VSD of the high-side MOSFET 121 being high and the drain-source voltage VDS of the low-side MOSFET 122 being low. Therefore, the parasitic capacitance Crgl is extremely large, and the detection sensitivity in detecting the capacitance of the sensor electrode 110 is greatly reduced.

On the other hand, the sensor device 100 has the node 123 at the voltage V3 (V2<V3<V1), which makes it possible to realize a state in which the source-drain voltage VSD of the high-side MOSFET 121 is high and the drain-source voltage VDS of the low-side MOSFET 122 is high.

Therefore, the parasitic capacitance Coss of the high-side MOSFET 121 of the sensor device 100 of the embodiment is, for example, a small value (approximately 200 pF) as indicated by a white circle (○) in FIG. 4A, and the parasitic capacitance Coss of the low-side MOSFET 122 of the sensor device 100 is, for example, a small value (approximately 200 pF) as indicated by a white circle (○) in FIG. 4B. The parasitic capacitance Coss of the high-side MOSFET 121 (approximately 200 pF) is a sufficiently small value, although being slightly larger than the parasitic capacitance Coss of the high-side MOSFET 121 of the comparative sensor device (approximately 150 pF). Moreover, the parasitic capacitance Coss of the low-side MOSFET 122 (approximately 200 pF) is a favorable value that is extremely smaller than the parasitic capacitance Coss of the low-side MOSFET 122 of the comparative sensor device (approximately 1,000 pF). The parasitic capacitance Coss of the high-side MOSFET 121 (approximately 200 pF) and the parasitic capacitance Coss of the low-side MOSFET 122 (approximately 200 pF) are substantially equal to each other.

The sum of the two parasitic capacitances Coss is approximately 400 pF, and the total parasitic capacitance is the parasitic capacitance Crgl between the sensor electrode 110 and the ground potential point. This means that the parasitic capacitance Crgl between the sensor electrode 110 and the ground potential point is extremely small.

Therefore, in the sensor device 100 of the embodiment, it is possible to make the parasitic capacitances Coss of both the high-side MOSFET 121 and the low-side MOSFET 122 small, which makes the parasitic capacitance Crgl extremely small. Therefore, it is possible to obtain a good detection sensitivity by minimizing the decrease in the detection sensitivity in detecting the capacitance of the sensor electrode 110.

More specifically, the sensor device 100 of the embodiment can reduce the parasitic capacitance Crgl by approximately 65% as compared with the comparative sensor device. Therefore, it is possible to obtain good detection sensitivity by minimizing a decrease in the detection sensitivity in detecting the capacitance of the sensor electrode 110.

This small parasitic capacitance Crgl is realized by setting the voltage V3 of the node 123 to an appropriate value. This only needs the voltage V3 to be set to a value optimized such that the parasitic capacitance Crgl becomes small, which only needs the resistance values of the resistors R1 and R2 to be set to appropriate values. For example, the appropriate resistance values of the resistors R1 and R2 are equal to each other.

### Modified Examples

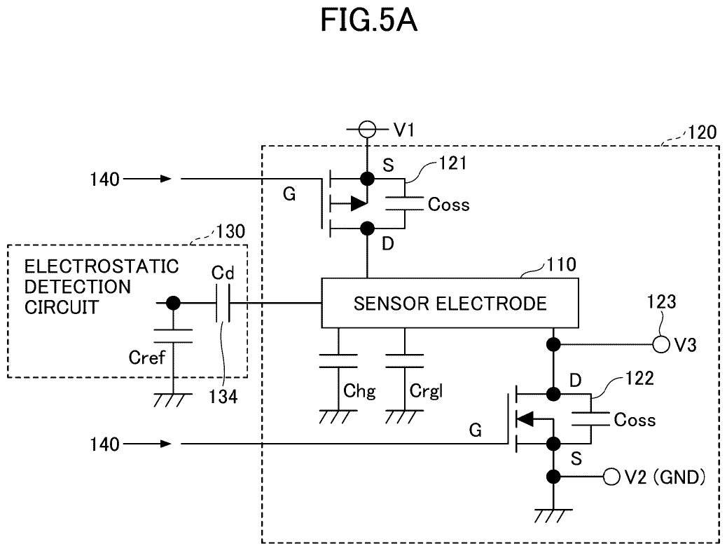

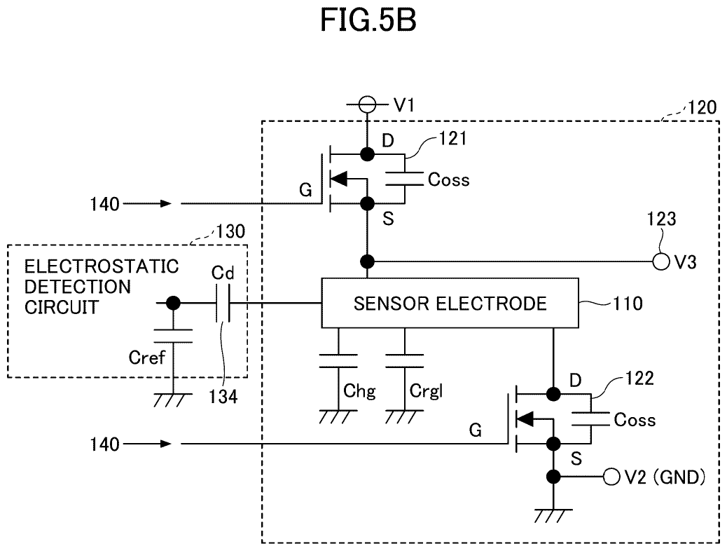

FIGS. 5A and 5B show an example of the circuit configuration of a part of the sensor device 100 according to modified examples of the embodiment. FIGS. 5A and 5B show a part of the sensor device 100 corresponding to the part shown in FIG. 3.

### Circuit Configuration Shown in FIG. 5A

In FIG. 5A, the node 123 is connected between the sensor electrode 110 and the drain of the low-side MOSFET 122. The voltage V3 of the node 123 may be the same as the voltage V3 of the node 123 shown in FIG. 3.

In the circuit configuration shown in FIG. 5A, the node 123 is connected to the drain of the high-side MOSFET 121 via the sensor electrode 110, and the node 123 is directly connected to the drain of the low-side MOSFET 122. Therefore, the source-drain voltage VSD of the high-side MOSFET 121 and the drain-source voltage VDS of the low-side MOSFET 122 shown in FIG. 5A are substantially equivalent to the source-drain voltage VSD of the high-side MOSFET 121 and the drain-source voltage VDS of the low-side MOSFET 122 of the sensor device 100 shown in FIG. 3.

Therefore, in the circuit configuration in which the node 123 is connected between the sensor electrode 110 and the drain of the low-side MOSFET 122 as shown in FIG. 5A as well, the parasitic capacitances Coss of both the high-side MOSFET 121 and the low-side MOSFET 122 can be reduced. This makes it possible to obtain a good detection sensitivity by minimizing the decrease in the detection sensitivity in detecting the capacitance of the sensor electrode 110.

### Circuit Configuration Shown in FIG. 5B

In FIG. 5B, the high-side MOSFET 121 is replaced with an N-channel MOSFET. The N-channel high-side MOSFET 121 has a connection relationship of the version of the P-channel high-side MOSFET 121 having its source and drain positionally exchanged.

When driving the N-channel high-side MOSFET 121, the control circuit 140 needs only to invert the H level and the L level from when driving the high-side MOSFET 121 shown in FIG. 3.

Thus, when the high-side MOSFET 121 is an N-channel MOSFET, it is possible to obtain a good detection sensitivity by minimizing the decrease in the detection sensitivity when detecting the capacitance of the sensor electrode 110 as well, as with the sensor device 100 shown in FIGS. 2 and 3.

### Effect

The sensor device 100 includes the sensor electrode 110 operable as a heating element, the electrostatic detection circuit 130 for detecting the capacitance between the sensor electrode 110 and an object, the high-side MOSFET 121 provided between the power source 51 for supplying power for heating to the sensor electrode 110 and the sensor electrode 110, the low-side MOSFET 122 provided between the sensor electrode 110 and the reference potential point, the node 23 located between the high-side MOSFET 121 or the low-side MOSFET 122 and the sensor electrode 110, and the control circuit 40 for controlling the high-side MOSFET 121 and the low-side MOSFET 122, wherein the control circuit 140 controls the high-side MOSFET 121 and the low-side MOSFET 122 to be in a conductive state when supplying power for heating from the power source 51 to the sensor electrode 110, and controls the high-side MOSFET 121 and the low-side MOSFET 122 to be in an open state and applies the voltage V3 to the node 123 when detecting the capacitance with the electrostatic detection circuit 130. Therefore, the voltages between the drain and the source of the high-side MOSFET 121 and those of the low-side MOSFET 122 can be high voltages of a certain level, which makes it possible to obtain a good detection sensitivity by minimizing the decrease in the detection sensitivity when detecting the capacitance of the sensor electrode 110. Further, since there are few components involved, the configuration is simple.

Therefore, it is possible to provide a sensor device 100 having good detection sensitivity and a simple configuration.

Further, the voltage V3 may be an intermediate voltage between the supply voltage (V1) supplied from the power source 51 to the high-side MOSFET 121 and the voltage at the reference potential point (GND). By using the voltage V3, which is an intermediate voltage between the voltage V1 and the voltage GND, it is possible to increase the voltage of a terminal of the low-side MOSFET 122 on the sensor electrode 110 side, and realize a state in which the parasitic capacitances Coss of the high-side MOSFET 121 and the low-side MOSFET 122 are small. Thus, it is possible to provide a sensor device 100 having good detection sensitivity and a simple configuration.

Further, the voltage V3 may be a voltage obtained by adding half the voltage difference between the supply voltage (V1) and the voltage at the reference potential point (GND) to the voltage at the reference potential point (GND). By using the voltage V3, which is the middle value between the voltage V1 and the voltage GND, it is possible to increase the voltage of the terminal of the low-side MOSFET 122 on the sensor electrode 110 side, and realize a state in which the parasitic capacitances Coss of the high-side MOSFET 121 and the low-side MOSFET 122 are small and the parasitic capacitances Coss of the high-side MOSFET 121 and the low-side MOSFET 122 are balanced. In this way, it is possible to provide a sensor device 100 having good detection sensitivity and a simple configuration.

Further, the voltage V3 may be a voltage that makes the parasitic capacitance Coss of the high-side MOSFET 121 and the parasitic capacitance Coss of the low-side MOSFET 122 equal or similar to each other. By using the voltage V3 that makes the parasitic capacitances Coss of the high-side MOSFET 121 and the low-side MOSFET 122 equal or similar to each other, it is possible to realize a state in which the parasitic capacitances Coss of the high-side MOSFET 121 and the low-side MOSFET 122 are small and the parasitic capacitances Coss of the high-side MOSFET 121 and the low-side MOSFET 122 are balanced. In this way, it is possible to provide a sensor device 100 having good detection sensitivity and a simple configuration.

Further, the resistor R1 connected between the power source 51 and the node 123, and the resistor R2 connected between the node 123 and the reference potential point may further be provided, and the voltage V3 may be a voltage divided in accordance with the resistor R1 and the resistor R2. Dividing the voltage of the power source 51 in accordance with the resistors R1 and R2 enables the voltage V3 to be obtained easily, and enables a stable voltage V3 to be obtained. Therefore, it is possible to provide a sensor device 100 having a good detection sensitivity, a simple configuration, and a stable operation.

Further, the resistor R1 connected between the power source 51 and the node 123, and the resistor R2 connected between the node 123 and the reference potential point may further be provided, wherein the voltage V3 is a voltage divided in accordance with the resistors R1 and R2, and the resistance values of the resistors R1 and R2 may be equal to each other. Dividing the voltage of the power source 51 in accordance with the resistors R1 and R2 enables the voltage V3 to be obtained easily, and enables a stable voltage V3 to be obtained. In addition, since the resistance values of the resistors R1 and R2 are equal to each other, the voltage V3 becomes a middle value between the voltage V1 and the voltage GND. Therefore, it is possible to realize a state in which the parasitic capacitances Coss of the high-side MOSFET 121 and the low-side MOSFET 122 are small and the parasitic capacitances Coss of the high-side MOSFET 121 and the low-side MOSFET 122 are balanced. In this way, it is possible to provide a sensor device 100 having good detection sensitivity and a simple configuration.

Moreover, the electrical characteristics of the high-side MOSFET 121 and the electrical characteristics of the low-side MOSFET 122 may be equal to each other. When the electrical characteristics of the high-side MOSFET 121 and the low-side MOSFET 122 are equal to each other, it is easy to set the parasitic capacitances Coss of the high-side MOSFET 121 and the low-side MOSFET 122. In this way, it is possible to provide a sensor device 100 that has good detection sensitivity and a simple configuration, and in which it is easy to set the parasitic capacitances Coss of the high-side MOSFET 121 and the low-side MOSFET 122.

The control circuit 140 may periodically drive the high-side MOSFET 121 and the low-side MOSFET 122 when supplying the power for heating from the power source 51 to the sensor electrode 110. Heating can be efficiently performed in accordance with the target value when the sensor electrode 110 is used as a heater, the current temperature of the heater, and the like.

Further, the AC signal source 132 capable of supplying a sinusoidal signal to the sensor electrode 110 may further be provided, and the control circuit 140 may cause the AC signal source 132 to supply a sinusoidal signal to the sensor electrode 110 when detecting capacitance with the electrostatic detection circuit 130. It is possible to determine the presence or absence of an object with high accuracy in a state in which the sinusoidal signal is supplied to the sensor electrode 110.

Further, the capacitor Cd for DC separation provided between the AC signal source 132 and the sensor electrode 110 may further be provided. It is possible to accurately detect the capacitance of the sensor electrode 110 by separating the electrostatic detection circuit 130 from the DC signal.

The node 123 may be provided between the sensor electrode 110 and the high-side MOSFET 121. With such a circuit configuration, it is possible to provide a sensor device 100 having a good detection sensitivity and a simple configuration.

The node 123 may be provided between the sensor electrode 110 and the low-side MOSFET 122. With such a circuit configuration, it is possible to provide a sensor device 100 having good detection sensitivity and a simple configuration.

The high-side MOSFET 121 may be a P-channel MOSFET, and the low-side MOSFET 122 may be an N-channel MOSFET. With such a circuit configuration, it is possible to provide a sensor device 100 having good detection sensitivity and a simple configuration.

The high-side MOSFET 121 and the low-side MOSFET 122 may be N-channel MOSFETs. With such a circuit configuration, it is possible to provide a sensor device 100 having good detection sensitivity and a simple configuration.

Although the sensor device of an illustrative embodiment of the present disclosure has been described above, the present disclosure is not limited to the specifically disclosed embodiment, and various modifications and changes are applicable without departing from the scope of the claims.

Regarding the above embodiments, the following appendices are further disclosed.

### Appendix 1

A sensor device, including:
a sensor electrode operable as a heating element;
an electrostatic detection circuit configured to detect a capacitance between the sensor electrode and an object;
a high-side switch provided between a power source for supplying power for heating to the sensor electrode and the sensor electrode;
a low-side switch provided between the sensor electrode and a reference potential point;
a node positioned between the high-side switch or the low-side switch and the sensor electrode; and
a controller configured to control the high-side switch and the low-side switch,
wherein the controller controls the high-side switch and the low-side switch to be in electrical conduction with each other when supplying the power for heating from the power source to the sensor electrode, and
the controller controls the high-side switch and the low-side switch to be in an open state and applies a predetermined voltage to the node when detecting the capacitance with the electrostatic detection circuit.

### Appendix 2

The sensor device according to Appendix 1,
wherein the predetermined voltage is an intermediate voltage between a supply voltage supplied from the power source to the high-side switch and a voltage at the reference potential point.

### Appendix 3

The sensor device according to Appendix 2,
wherein the predetermined voltage is a voltage obtained by adding half a voltage difference between the supply voltage and the voltage at the reference potential point to the voltage at the reference potential point.

### Appendix 4

The sensor device according to any one of Appendices 1 to 3,
wherein the predetermined voltage is a voltage that makes a first parasitic capacitance of the high-side switch and a second parasitic capacitance of the low-side switch equal or similar to each other.

### Appendix 5

The sensor device according to Appendix 2, further including:
a first voltage-dividing resistor connected between the power source and the node; and
a second voltage-dividing resistor connected between the node and the reference potential point,
wherein the predetermined voltage is a voltage divided in accordance with the first voltage-dividing resistor and the second voltage-dividing resistor.

### Appendix 6

The sensor device according to Appendix 3, further including:
a first voltage-dividing resistor connected between the power source and the node; and
a second voltage-dividing resistor connected between the node and the reference potential point,
wherein the predetermined voltage is a voltage divided in accordance with the first voltage-dividing resistor and the second voltage-dividing resistor, and
resistance values of the first voltage-dividing resistor and the second voltage-dividing resistor are equal to each other.

### Appendix 7

The sensor device according to Appendix 6,
wherein electrical characteristics of the high-side switch are equal to electrical characteristics of the low-side switch.

### Appendix 8

The sensor device according to any one of Appendices 1 to 7,
wherein the controller periodically drives the high-side switch and the low-side switch when supplying the power for heating from the power source to the sensor electrode.

### Appendix 9

The sensor device according to any one of Appendices 1 to 8, further including:
a sinusoidal signal source capable of supplying a sinusoidal signal to the sensor electrode,
wherein the controller controls the sinusoidal signal source to supply the sinusoidal signal to the sensor electrode when detecting the capacitance with the electrostatic detection circuit.

### Appendix 10

The sensor device according to Appendix 9, further including:
a capacitor for direct-current separation provided between the sinusoidal signal source and the sensor electrode.

### Appendix 11

The sensor device according to any one of Appendices 1 to 10,
wherein the node is provided between the sensor electrode and the high-side switch.

### Appendix 12

The sensor device according to any one of Appendices 1 to 10,
wherein the node is provided between the sensor electrode and the low-side switch.

### Appendix 13

The sensor device according to any one of Appendices 1 to 12,
wherein the high-side switch is a P-channel MOSFET, and
the low-side switch is an N-channel MOSFET.

### Appendix 14

The sensor device according to any one of Appendices 1 to 12,
wherein each of the high-side switch and the low-side switch are an N-channel MOSFET.

What is claimed is:

1. A sensor device, comprising:
a sensor electrode operable as a heating element;
an electrostatic detection circuit configured to detect a capacitance between the sensor electrode and an object;
a high-side switch provided between a power source for supplying power for heating to the sensor electrode and the sensor electrode;
a low-side switch provided between the sensor electrode and a reference potential point;
a node positioned between the high-side switch or the low-side switch and the sensor electrode; and
a controller configured to control the high-side switch and the low-side switch,
wherein the controller controls the high-side switch and the low-side switch to be in electrical conduction with each other when supplying the power for heating from the power source to the sensor electrode, and
the controller controls the high-side switch and the low-side switch to be in an open state and applies a predetermined voltage to the node when detecting the capacitance with the electrostatic detection circuit.

2. The sensor device according to claim 1,
wherein the predetermined voltage is an intermediate voltage between a supply voltage supplied from the power source to the high-side switch and a voltage at the reference potential point.

3. The sensor device according to claim 2,
wherein the predetermined voltage is a voltage obtained by adding half a voltage difference between the supply voltage and the voltage at the reference potential point to the voltage at the reference potential point.

4. The sensor device according to claim 1,
wherein the predetermined voltage is a voltage that makes a first parasitic capacitance of the high-side switch and a second parasitic capacitance of the low-side switch equal or similar to each other.

5. The sensor device according to claim 2, further comprising:
a first voltage-dividing resistor connected between the power source and the node; and
a second voltage-dividing resistor connected between the node and the reference potential point,
wherein the predetermined voltage is a voltage divided in accordance with the first voltage-dividing resistor and the second voltage-dividing resistor.

6. The sensor device according to claim 3, further comprising:
a first voltage-dividing resistor connected between the power source and the node; and
a second voltage-dividing resistor connected between the node and the reference potential point,
wherein the predetermined voltage is a voltage divided in accordance with the first voltage-dividing resistor and the second voltage-dividing resistor, and
resistance values of the first voltage-dividing resistor and the second voltage-dividing resistor are equal to each other.

7. The sensor device according to claim 6,
wherein electrical characteristics of the high-side switch are equal to electrical characteristics of the low-side switch.

8. The sensor device according to claim 1,
wherein the controller periodically drives the high-side switch and the low-side switch when supplying the power for heating from the power source to the sensor electrode.

9. The sensor device according to claim 1, further comprising:
a sinusoidal signal source capable of supplying a sinusoidal signal to the sensor electrode,
wherein the controller controls the sinusoidal signal source to supply the sinusoidal signal to the sensor electrode when detecting the capacitance with the electrostatic detection circuit

10. The sensor device according to claim 9, further comprising:
a capacitor for direct-current separation provided between the sinusoidal signal source and the sensor electrode.

11. The sensor device according to claim 1,
wherein the node is provided between the sensor electrode and the high-side switch.

12. The sensor device according to claim 1,
wherein the node is provided between the sensor electrode and the low-side switch.

13. The sensor device according to claim 1,
wherein the high-side switch is a P-channel MOSFET, and
the low-side switch is an N-channel MOSFET.

14. The sensor device according to claim 1,
wherein each of the high-side switch and the low-side switch are an N-channel MOSFET.
